(19) United States
(12) Patent Application Publication
(10) Pub. No.: US 2024/0014717 A1
(43) Pub. Date: Jan. 11, 2024

(54) STATOR MANUFACTURING METHOD

(71) Applicant: TOYOTA JIDOSHA KABUSHIKI KAISHA, Aichi-ken (JP)

(72) Inventors: Masashi MATSUMOTO, Nagoya-shi (JP); Ken SHIRAI, Toyota-shi (JP); Hazuki KAWAMURA, Nisshin-shi (JP); Kohei WATANABE, Okazaki-shi (JP)

(21) Appl. No.: 18/313,371

(22) Filed: May 8, 2023

(30) Foreign Application Priority Data
Jul. 11, 2022 (JP) 2022-111150

(51) Int. Cl. H02K 15/00; G01R 31/34

(52) U.S. Cl. CPC H02K 15/0081; G01R 31/34

(57) ABSTRACT

A stator manufacturing method includes an inserting step of inserting lead-side segment coils covered with an insulating film and lead-opposite-side segment coils covered with an insulating film into a plurality of slots formed between a plurality of teeth radially protruding from an annular yoke, along the axial direction of the yoke, and electrically connecting the segment coils by using connecting members, in the inserting step, the plurality of segment coils are collectively inserted into the slots, and the method further includes an exposing step of forming the segment coils with exposed conductor portions by forming holes penetrating the insulating films in crossover parts of the segment coils while the segment coils are inserted in the slots.

### CROSS-REFERENCE TO RELATED APPLICATION

This application claims priority to Japanese Patent Application No. 2022-111150 filed on Jul. 11, 2022, incorporated herein by reference in its entirety.

### BACKGROUND

### 1. Technical Field

The present disclosure relates to a stator manufacturing method.

### 2. Description of Related Art

Japanese Unexamined Patent Application Publication No. 2020-102980 (JP 2020-102980 A) describes a stator manufacturing method that electrically connects lead-side segment coils and lead-opposite-side segment coils to each other by using hollow connecting members. In the manufacturing method described in JP 2020-102980 A, each pair of lead-side segment coil and lead-opposite-side segment coil is inserted into each slot of the stator core, and both segment coils are connected to each other by the connecting member. Subsequently, probes are brought into contact with exposed conductor portions of both segment coils located in the slot to perform resistance measurement, to thereby inspect the electrical connection between both segment coils.

### SUMMARY

Unfortunately, in JP 2020-102980 A, since the exposed conductor portions of the segment coils are located in the slot, it is necessary to perform the inspection by the resistance measurement every time each pair of segment coils is inserted into each slot from the outer circumference side toward the inner circumference side of the stator core. In other words, it is necessary to repetitively perform a step of inserting each pair of segment coils into each slot and carrying out the inspection by the resistance measurement. Hence, this causes a problem that increases the number of steps in the process of assembling the segment coils to the stator core.

The present disclosure has been made in order to solve the above problem, and an object of the disclosure is to provide a stator manufacturing method that facilitates the process of assembling segment coils to a stator core in a simpler manner.

A stator manufacturing method according to a first aspect of the present disclosure includes an inserting step of inserting lead-side segment coils covered with an insulating film and lead-opposite-side segment coils covered with an insulating film into a plurality of slots formed between a plurality of teeth radially protruding from an annular yoke, along the axial direction of the yoke, and electrically connecting ends of the lead-side segment coils and ends of the lead-opposite-side segment coils by using connecting members, in the inserting step, the lead-side segment coils and the lead-opposite-side segment coils are collectively inserted into the slots, the stator manufacturing method further including an exposing step of forming the lead-side segment coils and the lead-opposite-side segment coils with exposed conductor portions by forming holes penetrating the insulating films at coil ends of the lead-side segment coils and coil ends of the lead-opposite-side segment coils while the segment coils are inserted in the slots.

According to the stator manufacturing method of the first aspect of the present disclosure, in the exposing step, the coil ends of the segment coils are formed with the exposed conductor portions, and probes are brought to contact with the exposed conductor portions to perform the inspection by the resistance measurement. Accordingly, the plurality of segment coils can be collectively inserted into the slots. In addition, after the plurality of segment coils are inserted into the slots, the plurality of segment coils can be collectively subjected to the inspection by the resistance measurement. Accordingly, it is possible to provide the stator manufacturing method that facilitates the process of assembling the segment coils to the stator core in a simper manner.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a perspective view showing an example of a stator according to Embodiment 1 of the present disclosure;

FIG. 2 is a sectional view showing an example of a stator core according to Embodiment 1 of the present disclosure;

FIG. 3 is a sectional view explaining a stator manufacturing method according to Embodiment 1 of the present disclosure;

FIG. 4 is a sectional view explaining the stator manufacturing method according to Embodiment 1 of the present disclosure;

FIG. 5 is a view explaining holes for conductor exposure, formed at a coil end in Embodiment 1 of the present disclosure;

FIG. 6 is a sectional view explaining a stator manufacturing method according to Comparative example; and

FIG. 7 is a partially enlarged sectional view showing connecting parts between lead-side segment coils and lead-opposite-side segment coils of the stator in Comparative example.

### DETAILED DESCRIPTION OF EMBODIMENTS

### Embodiment 1

Embodiment 1 of the present disclosure will be described with reference to the drawings, hereinafter. It should be noted that the present disclosure is not limited to Embodiment 1 below. For clarity of explanation, the following description and drawings are simplified as appropriate.

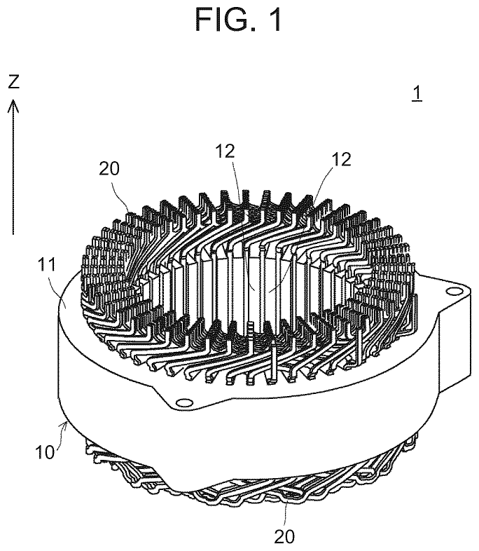

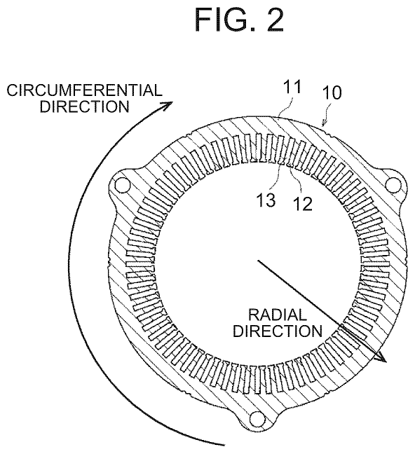

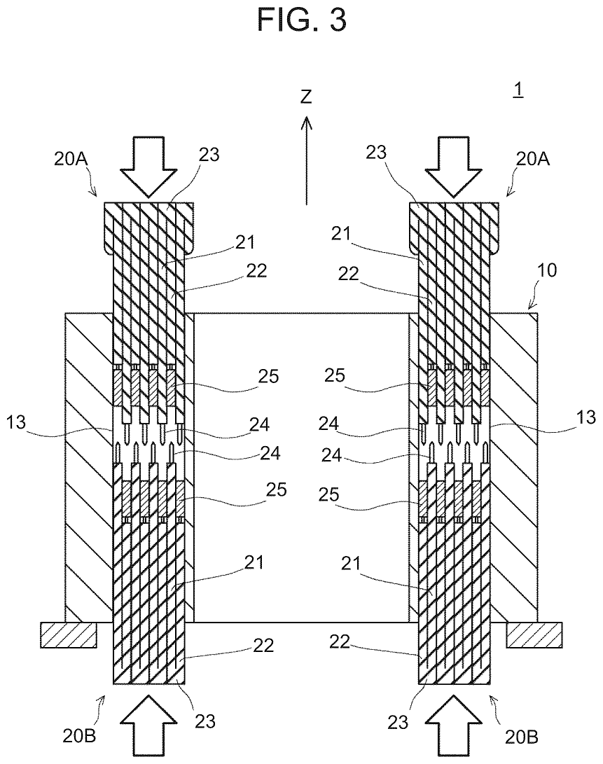

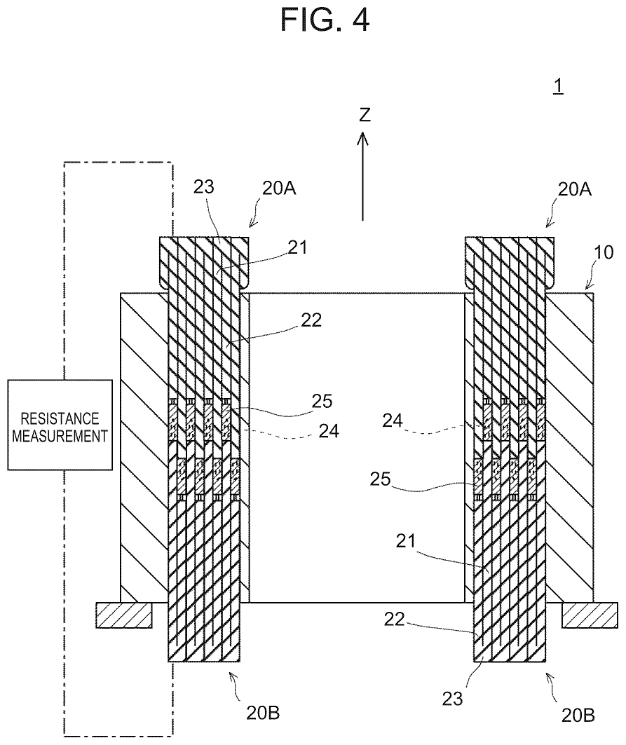

FIG. 1 is a perspective view showing an example of a stator 1 according to Embodiment 1. FIG. 2 is a sectional view showing an example of a stator core 10. FIG. 2 shows a section of the stator core 10 taken along a plane perpendicular to the axial direction (Z-axis direction) of the stator 1. FIG. 3 and FIG. 4 are sectional views each explaining the stator manufacturing method according to Embodiment 1. FIG. 3 and FIG. 4 each show a section of the stator 1 taken along a plane parallel to the axial direction (Z-axis direction) of the stator 1.

The stator 1 is a stator used for a rotary electric machine. The rotary electric machine, in which the stator 1 is used, includes the stator 1 as shown in FIG. 1 and a rotor (not shown) arranged on the inner circumferential side of the stator 1 at a predetermined interval therebetween. The rotary electric machine in which the stator 1 is used may be configured in combination with a rotor (not shown) arranged on the outer circumferential side of the stator 1 at a predetermined interval therebetween. As shown in FIG. 1 and FIG. 2, the stator 1 includes the stator core 10, a plurality of segment coils 20, and others.

The stator core 10 is formed by stacking annular thin magnetic plates in the axial direction (Z-axis direction in FIG. 1) of the stator 1, and has a substantially cylindrical shape as a whole. In FIG. 2, the radial direction and the circumferential direction are shown. The axial direction is a direction along the central axis of a center hole of the stator core 10. The radial direction is a direction extending radially and passing through the central axis within a plane perpendicular to the axial direction, and the circumferential direction is a direction along the circumference around the central axis.

The stator core 10 includes a yoke 11, teeth 12, and slots 13. A plurality of teeth 12, radially projecting from a plurality of positions on the inner circumferential surface of the ring-shaped yoke 11, are formed at predetermined intervals. Each slot 13 is formed in a space between two adjacent teeth 12, 12.

The slot 13 has an opening shape extending along the radial direction of the stator core 10 as the longitudinal direction of the slot 13. In addition, the slot 13 opens toward the inner circumferential surface of the stator core 10. In this case, it is exemplified that each slot 13 has an inner circumference width that is constant through the radial direction. The width of each slot 13 may be formed to be gradually widened radially outward, or conversely, may be formed to be gradually narrower radially outward.

Each slot 13 of the stator core 10 is wound with three-phase (U-phase, V-phase, and W-phase) coils. The number of the slots 13 formed on the stator core 10 is set to correspond the number of magnetic poles of the rotor. A plurality of segment coils 20 are arranged side by side in the longitudinal direction of the slots 13.

The segment coil 20 is formed by using a plurality of generally U-shaped conductor segments. Each conductor segment is formed, for example, by forming a rectangular conductor having a rectangular section into a substantially U shape. Each segment coil 20 is covered with an insulating film. Specifically, as shown in FIG. 3 and FIG. 4, each segment coil 20 includes: two legs 21, 22 parallel to each other; and a crossover part 23 connecting these legs. One of the two legs 21, 22 is longer than the other. In an example shown in FIG. 3 and FIG. 4, the leg 21 is longer than the leg 22. Each end of the two legs 21, 22 is provided with an insertion portion 24 that is insertable into a connecting member 25, which will be described later. The insertion portion 24 of the leg 22 is previously inserted into the connecting member 25 which is a metallic tube, such as a hollow copper tube. Each segment coil 20 is inserted from the two legs 21, 22 into each slot 13 along the axial direction of the stator core 10. The crossover parts 23 connecting the two legs 21, 22 protrude outward of an axial end face of the stator core 10.

Further, each segment coil 20 inserted into each slot 13 from the lead side of the stator core 10 (the upper side in FIG. 3, FIG. 4) is referred to as a lead-side segment coil 20A, and each segment coil 20 inserted into each slot 13 from the side opposite to the lead side of the stator core 10 (the lower side in FIG. 3, FIG. 4) is referred to as a lead-opposite-side segment coil 20B. The lead-side segment coil 20A and the lead-opposite-side segment coil 20B are simply referred to as the segment coils 20 when they are not required to be particularly distinguished from each other. The insertion portion 24 of the leg 21 of the lead-side segment coil 20A is inserted into the connecting member 25 in which the insertion portion 24 of the leg 22 of the lead-opposite-side segment coil 20B facing the lead-side segment coil 20A is previously inserted. Accordingly, the lead-side segment coil 20A and the lead-opposite-side segment coil 20B are electrically connected to each other. The insertion portion 24 inserted into the connecting member 25 and this connecting member 25 are covered with no insulating film.

Although FIG. 3 and FIG. 4 are simplified, in reality, the plurality of segment coils 20 arranged side by side in the radial direction of the stator core 10 are inserted into two slots 13 arranged apart in the circumferential direction. A portion of the segment coil 20 protruding from one axial end face of the stator core 10 is bent to be inclined with respect to the axial direction of the stator core 10.

Next, the stator manufacturing method of Embodiment 1 of the present disclosure will be described with reference to FIG. 3 and FIG. 4. Hereinafter, among the processes of the stator manufacturing method, an assembly process of assembling the segment coils 20 to the stator core 10 will be described. Specifically, the assembly process includes an inserting step and an exposing step.

In the inserting step, the lead-side segment coils 20A and the lead-opposite-side segment coil 20B are inserted into the plurality of slots 13 of the stator core 10 and the ends of the lead-side segment coils 20A and the ends of the lead-opposite-side segment coils are electrically connected by the connecting members 25. Specifically, in the stator manufacturing method according to Embodiment 1, in this inserting process, the plurality of lead-side segment coils 20A and the plurality of lead-opposite-side segment coils 20B are collectively inserted into the slots 13. The insertion of the plurality of segment coils 20 into the slots 13 is carried out by pressing the segment coils by a jig (not shown) having a flat surface facing coil ends (crossover parts 23) of the segment coils 20.

In the exposing step, each lead-side segment coil 20A and each lead-opposite-side segment coil 20B are formed with exposed conductor portions by forming holes 26 (described later) penetrating the insulating films at the coil end of the lead-side segment coil 20A and the coil end of the lead-opposite-side segment coil 20B while both segment coils 20A, 20B are inserted in the slot 13. In the exposing step, the holes 26 may be formed in the insulating film by sticking a probe for resistance measurement into the insulating film.

As shown in FIG. 4, probes are brought into contact with the exposed conductor portions, which are formed by forming the holes 26 in the insulating films, and thereby the resistance is measured to inspect whether or not normal electrical connection is made between the lead-side segment coil 20A and the lead-opposite-side segment coil 20B.

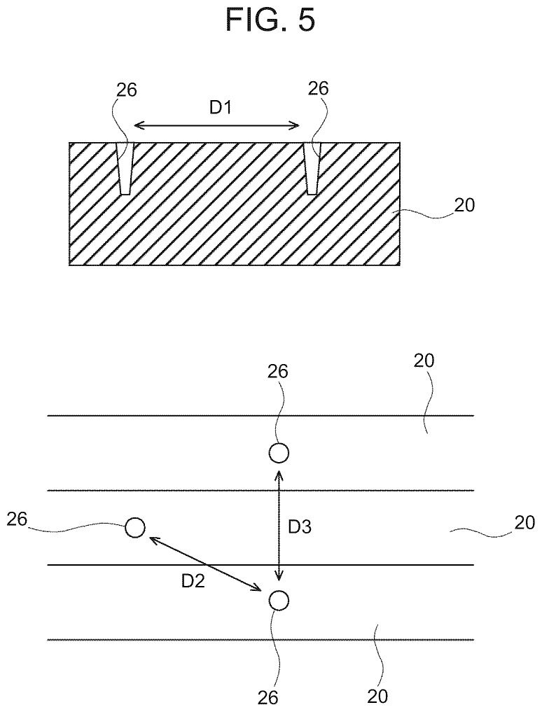

FIG. 5 shows a diagram explaining the holes 26 for the conductor exposure formed in each coil end. The upper part in FIG. 5 shows an enlarged section of the segment coil 20 when the stator 1 is cut along a plane parallel to the axial direction of the stator core 10. The lower part in FIG. 5 is a top view showing the holes 26 formed in the plurality of segment coils 20 adjacently arranged. As shown in FIG. 5, in the exposing step, as for the holes 26 formed in the coil ends (crossover parts 23) of the plurality of segment coils 20, the holes 26 are formed such that respective distances D1, D2, D3 between the adjacent holes 26 are arranged to secure electric insulation among the plurality of segment coils. The respective distances D1, D2, D3 between the adjacent holes 26 are distances between respective top edges of these holes 26. Each hole 26 has a diameter small enough to secure electric insulation between the plurality of segment coils and large enough to allow the probe for the resistance measurement to contact with the exposed conductor portion. The shape of each hole 26 is not limited to the shape shown in FIG. 5, and for example, each hole 26 may have substantially the same diameter along the depth direction thereof.

### Comparative Example

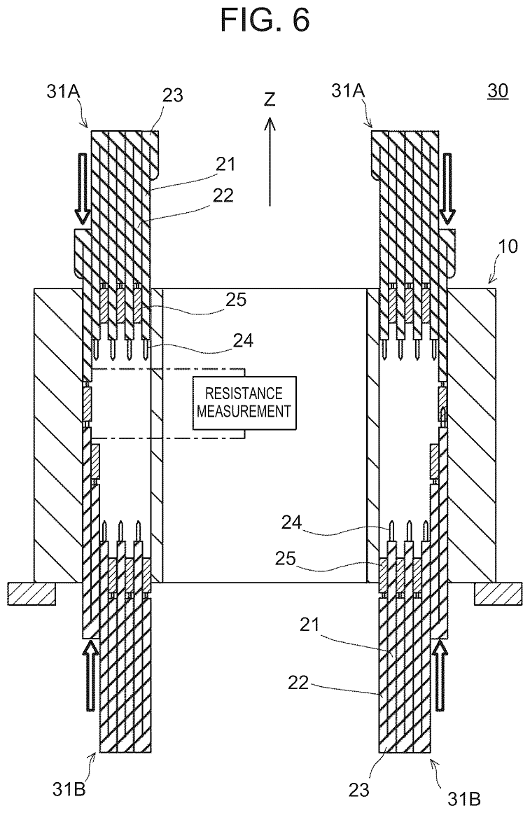

Next, with reference to FIG. 6, a stator manufacturing method according to Comparative example will be described, hereinafter. The configurations of a stator 30 according to Comparative example, which are the same as or similar to those of the stator 1 according to Embodiment 1, are denoted by the same reference numerals. In Comparative example, the insulating film at the ends of the legs 21, 22 of each segment coil 31 is removed to form an exposed conductor portion 32. As shown in FIG. 6, each pair of lead-side segment coil 31A and lead-opposite-side segment coil 31B is inserted into each slot of the stator core 10, and both segment coils 31A, 31B are connected to each other by the connecting member 25. Then, the probes are brought into contact with the exposed conductor portions 32 of both segment coils 31A, 31B located in the slot 13, and the resistance measurement is carried out to inspect the electrical connection between both segment coils 31A, 31B.

Hence, in Comparative example, since the exposed conductor portions 32 are located in the slot 13, every time each pair of segment coil 31A, 31B is inserted into each slot 13 from the outer circumference side to the inner circumference side of the stator core 10, it is necessary to carry out the inspection by the resistance measurement. In other words, it is necessary to repetitively perform the step of inserting each pair of segment coils 31A, 31B into each slot 13 and carrying out the inspection by the resistance measurement. Therefore, this causes a problem that increases the number of steps in the process of assembling the segment coils 31 to the stator core 10.

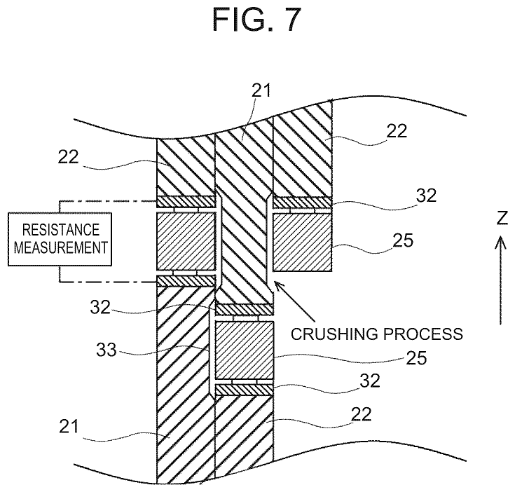

In addition, in Comparative example, as shown in FIG. 7, in order to secure electric insulation between the adjacent segment coils 31 in the slot 13, a cut-out 33 is formed in a portion of the leg 21, the portion facing the exposed conductor portion 32 and the connecting member 25. The cut-out 33 can be formed by crushing a portion to be cut-out of the leg 21. However, in general, since it is difficult to process a bulge (metal) generated by this crushing, the wider the area to be crushed, the more difficult it is to process the segment coil 31.

In contrast, according to the stator manufacturing method of Embodiment 1, in the exposing step, the coil ends (crossover parts 23) of the segment coils 20 are formed with the exposed conductor portions, and the probes are brought into contact with the exposed conductor portions, to thereby perform the inspection by carrying out the resistance measurement. Therefore, it is possible to insert the plurality of segment coils 20 into the slot 13 at one time. After the plurality of segment coils 20 are inserted into the slot 13, the plurality of segment coils 20 can be collectively inspected with the resistance measurement. Accordingly, it is possible to provide the stator manufacturing method that facilitates the process of assembling the segment coils 20 to the stator core 10 in a simpler manner.

In addition, since it is unnecessary to form the exposed conductor portions 32 at the ends of the legs 21, 22, it is possible to reduce an area in the leg 21 where the cut-out 33 is formed. Specifically, in Embodiment 1, the cut-out 33 may be provided only in a portion of the leg 21 facing the connecting member 25. Accordingly, it is possible to reduce an area of the leg 21 to be crushed, which facilitates the processing on the segment coils 31.

Further, in the exposing step, by sticking the probe for the resistance measurement into the insulating film to form the hole 26 in the insulating film, it is possible to perform formation of the exposed conductor portion and bringing the probe to contact with the exposed conductor portion at the same time; and it is possible to further simplify the stator manufacturing method.

In addition, as for the plurality of holes 26 formed at the coil ends (crossover parts 23) of the plurality of segment coils 20, the respective distances D1, D2, D3 between the adjacent holes 26 are distances that can secure electric insulation between the plurality of segment coils. As a result, it is possible to reduce adverse effects caused by formation of the holes 26 in the insulating film.

It should be noted that the present disclosure is not limited to the above-described embodiments and can be modified as appropriate without departing from the scope of the disclosure.

What is claimed is:

1. A stator manufacturing method, comprising
an inserting step of inserting lead-side segment coils covered with an insulating film and lead-opposite-side segment coils covered with an insulating film into a plurality of slots formed between a plurality of teeth radially protruding from an annular yoke, along an axial direction of the yoke, and electrically connecting ends of the lead-side segment coils and ends of the lead-opposite-side segment coils by using connecting members,
in the inserting step, the lead-side segment coils and the lead-opposite-side segment coils being collectively inserted into the slots,
the stator manufacturing method further comprising
an exposing step of forming the lead-side segment coils and the lead-opposite-side segment coils with exposed conductor portions by forming holes penetrating the insulating films at coil ends of the lead-side segment coils and coil ends of the lead-opposite-side segment coils while the segment coils are inserted in the slots.

2. The stator manufacturing method according to claim 1, wherein
in the exposing step, the holes are formed in the insulating film by sticking a probe for resistance measurement into the insulating film.

3. The stator manufacturing method according to claim 1, wherein
in the exposing step, a plurality of the holes, which are formed at the coil ends of the lead-side segment coils and the coil ends of the lead-opposite-side segment coils, are arranged such that distances between adjacent holes secure electric insulation between the lead-side segment coils and the lead-opposite-side segment coils.
